(19) United States
(12) Patent Application Publication
(10) Pub. No.: US 2026/0329180 A1
(43) Pub. Date: Oct. 22, 2026

(54) DRY BACKSIDE AND BEVEL EDGE CLEAN OF PHOTORESIST

(71) Applicant: Lam Research Corporation, Fremont, CA (US)

(72) Inventors: Daniel Peter, Sunnyvale, CA (US); Jengyi Yu, San Ramon, CA (US); Samantha S.H. Tan, Newark, CA (US); Meng Xue, Fremont, CA (US); Da Li, Newark, CA (US); Keith Edward Dawson, Livermore, CA (US); Clint Edward Thomas, Timnath, CO (US); John Danny Baterina Pacho, Hollister, CA (US)

(21) Appl. No.: 19/723,645

(22) Filed: Jun. 29, 2026

Related U.S. Application Data
(62) Division of application No. 18/011,707, filed on Jun. 17, 2021.
(60) Provisional application No. 62/705,333, filed on Jun. 22, 2020.

(51) Int. Cl. G03F 7/36; G03F 7/40

(52) U.S. Cl. CPC G03F 7/36; G03F 7/40

(57) ABSTRACT

Dry backside and bevel edge clean is performed without exposure to plasma to remove unwanted photoresist material from a substrate. The substrate is supported on a substrate support and elevated by minimum contact area (MCA) supports so that etch gas can access a backside of the substrate. A gas distributor delivers curtain gas to a frontside of the substrate to protect photoresist material on the frontside. An etch gas delivery source delivers a first etch gas flow to the backside, and one or more peripheral gas inlets deliver a second etch gas flow to a periphery of the frontside and around the bevel edge. A radiative heat source is positioned below the substrate to heat the substrate.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

The fabrication of semiconductor devices, such as integrated circuits, is a multi-step process involving photolithography. In general, the process includes the deposition of material on a wafer, and patterning the material through lithographic techniques to form structural features (e.g., transistors and circuitry) of the semiconductor device. The steps of a typical photolithography process known in the art include: preparing the substrate; applying a photoresist, such as by spin coating; exposing the photoresist to light in a desired pattern, causing the exposed areas of the photoresist to become more or less soluble in a developer solution; developing by applying a developer solution to remove either the exposed or the unexposed areas of the photoresist; and subsequent processing to create features on the areas of the substrate from which the photoresist has been removed, such as by etching or material deposition.

The evolution of semiconductor design has created the need, and has been driven by the ability, to create ever smaller features on semiconductor substrate materials. This progression of technology has been characterized in “Moore's Law” as a doubling of the density of transistors in dense integrated circuits every two years. Indeed, chip design and manufacturing has progressed such that modern microprocessors may contain billions of transistors and other circuit features on a single chip. Individual features on such chips may be on the order of 22 nanometers (nm) or smaller, in some cases less than 10 nm.

One challenge in manufacturing devices having such small features is the ability to reliably and reproducibly create photolithographic masks having sufficient resolution. Current photolithography processes typically use 193 nm ultraviolet (UV) light to expose a photoresist. The fact that the light has a wavelength significantly greater than the desired size of the features to be produced on the semiconductor substrate creates inherent issues. Achieving feature sizes smaller than the wavelength of the light requires use of complex resolution enhancement techniques, such as multipatterning. Thus, there is significant interest and research effort in developing photolithographic techniques using shorter wavelength light, such as extreme ultraviolet radiation (EUV), having a wavelength of from 10 nm to 15 nm, e.g., 13.5 nm.

EUV photolithographic processes can present challenges, however, including low power output and loss of light during patterning. Traditional organic chemically amplified resists (CAR) similar to those used in 193 nm UV lithography have potential drawbacks when used in EUV lithography, particularly as they have low absorption coefficients in EUV region and the diffusion of photo-activated chemical species can result in blur or line edge roughness. Furthermore, in order to provide the etch resistance required to pattern underlying device layers, small features patterned in conventional CAR materials can result in high aspect ratios at risk of pattern collapse. Accordingly, there remains a need for improved EUV photoresist materials, having such properties as decreased thickness, greater absorbance, and greater etch resistance.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

Provided herein is an apparatus for conducting bevel edge and backside clean of a substrate. The apparatus comprises a process chamber, a substrate support for supporting the substrate in the process chamber, a plurality of minimum contact area (MCA) supports configured to extend from the substrate support to contact a backside of the substrate, a gas distributor over the substrate support, the gas distributor having one or more central gas inlets for directing curtain gas flow at a center of a frontside of the substrate, an etch gas delivery source below the substrate support for directing a first etch gas flow to the backside of the substrate, and a radiative heat source below the substrate support.

In some implementations, the gas distributor further comprises one or more peripheral gas inlets for directing a second etch gas flow at a periphery of a frontside of the substrate. In some implementations, a first gap separating the one or more peripheral gas inlets from the frontside of the substrate is greater than a second gap separating the one or more central gas inlets from the frontside of the substrate. In some implementations, the gas distributor comprises a modular ring for the one or more peripheral gas inlets, the modular ring configured to modulate spacing of the one or more peripheral gas inlets from the frontside of the substrate. In some implementations, the substrate support comprises a carrier ring having an annular body for supporting the substrate. In some implementations, the carrier ring is configured to shift or rotate the position of the plurality of MCA supports for supporting the substrate at different contact points on the backside of the substrate. In some implementations, the plurality of MCA supports are configured to contact areas of the backside of the substrate having little to no photoresist deposits. In some implementations, the plurality of MCA supports are configured to position the substrate above the substrate support to permit the first etch gas flow across the backside of the substrate. In some implementations, the plurality of MCA supports comprise a first set of MCA supports and a second set of MCA supports, each of the first set of MCA supports and the second set of MCA supports being extendable/retractable for supporting the substrate. In some implementations, the etch gas delivery source comprises holes through the radiative heat source or holes positioned outside of the radiative heat source. In some implementations, the apparatus further comprises one or more heaters coupled to the gas distributor and above the substrate. In some implementations, the apparatus further comprises one or more sensors in the process chamber, the one or more sensors configured to detect a presence of film deposits on a bevel edge and backside of the substrate. In some implementations, the apparatus further comprises a controller configured with instructions for performing a bevel edge and backside clean of the substrate, the instructions comprising code for: providing the substrate in the process chamber, where the substrate comprises photoresist material deposited on the frontside, bevel edge, and backside of the substrate, extending the MCA supports to lift the substrate above the substrate support, heating the substrate to an elevated temperature using the radiative heat source, where the elevated temperature is between about 20° C. and about 170° C., introducing the first etch gas flow to the backside of the substrate, introducing the curtain gas flow to the center of the frontside of the substrate, and introducing a second etch gas flow to the periphery of the frontside of the substrate, where the first etch gas flow and the second etch gas flow removes at least the photoresist material from the bevel edge and backside of the substrate. In some implementations, an etch gas of the first etch gas flow and the second etch gas flow comprises a hydrogen halide, hydrogen gas and halide gas, or boron trichloride, and the photoresist material comprises an EUV resist material. In some implementations, an etch gas of the first etch gas flow and the second etch gas flow comprises an oxidizing gas, and the photoresist material comprises a carbon-based material. In some implementations, an etch gas of the first etch gas flow and the second etch gas flow comprises a fluorine-containing gas or chlorine-containing gas, and the photoresist material comprises a silicon-based material. In some implementations, a curtain gas of the curtain gas flow comprises nitrogen (N₂), oxygen (O₂), water (H₂O), argon (Ar), helium (He), xenon (Xe), or neon (Ne). In some implementations, the controller is further configured with instructions comprising code for: performing a post-application bake on the photoresist material by heating the substrate to a desired temperature in the same process chamber for removing the EUV photoresist material from the bevel edge and backside of the substrate. In some implementations, the controller is further configured with instructions comprising code for: purging the process chamber with purge gas after removing the photoresist material from the bevel edge and backside of the substrate. In some implementations, the controller is further configured with instructions comprising code for: dry depositing the photoresist material on the frontside, bevel edge, and backside of the substrate, wherein the deposition occurs in the same process chamber as removing the photoresist material from the bevel edge and backside of the substrate.

Also provided herein is a method of conducting bevel edge and backside clean of a substrate. The method comprises providing a substrate on a substrate support in a process chamber, where the substrate comprises a photoresist material on a frontside, bevel edge, and backside of the substrate, where the substrate is lifted above the substrate support to permit gas flow across the backside of the substrate, heating the substrate to an elevated temperature, where the elevated temperature is between about 20° C. and about 170° C., flowing curtain gas to a center of the frontside of the substrate, and flowing etch gas to the backside of the substrate, where the etch gas removes at least the photoresist material on the bevel edge and backside of the substrate.

In some implementations, flowing etch gas to the backside of the substrate comprises introducing a first etch gas flow to the backside of the substrate and introducing a second etch gas flow to a periphery of the frontside of the substrate. In some implementations, the first etch gas flow is flowed across the backside of the substrate, where the second etch gas flow is flowed along a periphery of the frontside the substrate and the bevel edge of the substrate, where the curtain gas limits the etch gas from flowing to a center of the frontside of the substrate. In some implementations, the first etch gas flow is introduced from one or more bottom gas inlets below the substrate support and the second etch gas flow is introduced from one or more peripheral gas inlets of a gas distributor above the substrate support. In some implementations, the curtain gas is flowed from one or more central gas inlets of a gas distributor, where a first gap separating the one or more peripheral gas inlets from the frontside of the substrate is greater than a second gap separating the one or more central gas inlets from the frontside of the substrate. In some implementations, the substrate is heated to the elevated temperature using a radiative heat source below the substrate support. In some implementations, the method further comprises lifting the substrate over the substrate support using a plurality of MCA supports to create a gap between the substrate support and the backside of the substrate. In some implementations, the etch gas comprises a hydrogen halide, hydrogen gas and halide gas, or boron trichloride, and the photoresist material comprises an EUV resist material. In some implementations, the etch gas comprises an oxidizing gas, and the photoresist material comprises a carbon-based material. In some implementations, the etch gas comprises a fluorine-based gas or chlorine-based gas, and the photoresist material comprises a silicon-based material. In some implementations, the curtain gas comprises nitrogen (N₂), oxygen (O₂), water (H₂O), argon (Ar), helium (He), xenon (Xe), or neon (Ne). In some implementations, the photoresist material comprises an organo-metal-oxide material. In some implementations, the method further comprises dry depositing the photoresist material on the frontside, bevel edge, and backside of the substrate, wherein the deposition occurs in the same process chamber as removing the photoresist material from the bevel edge and backside of the substrate. In some implementations, the method further comprises performing a post-application bake on the photoresist material by heating the substrate to a desired temperature in the same process chamber for removing the photoresist material from the bevel edge and backside of the substrate. In some implementations, the method further comprises purging the process chamber with purge gas after removing the photoresist material from the bevel edge and backside of the substrate.

### BRIEF DESCRIPTION OF DRAWINGS

FIG. 1 presents a flow diagram of an example method for depositing and developing a photoresist according to some embodiments.

FIGS. 2A-2D show cross-sectional schematic illustrations of various processing stages of conventional backside and bevel edge clean.

FIGS. 3A-3C show cross-sectional schematic illustrations of various processing stages of dry backside and bevel edge clean of photoresist according to some embodiments.

FIG. 4 shows a schematic illustration of a process chamber for performing dry backside and bevel edge clean according to some embodiments.

FIG. 5A shows a perspective view of a carrier ring for supporting a substrate in a process chamber according to some embodiments.

FIG. 5B shows a cross-sectional schematic illustration of a carrier ring supporting and contacting a backside of a substrate according to some embodiments.

FIG. 6 depicts a schematic illustration of an example process station for maintaining a low-pressure environment that is suitable for performing backside and bevel edge clean operations according to some embodiments.

FIG. 7 depicts a schematic illustration of an example multi-station processing tool suitable for implementation of various development, clean, rework, descum, and smoothing operations described herein.

FIG. 8 shows a cross-sectional schematic view of an example inductively-coupled plasma apparatus for implementing certain embodiments and operations described herein.

FIG. 9 depicts a semiconductor process cluster tool architecture with vacuum-integrated deposition and patterning modules that interface with a vacuum transfer module, suitable for implementations of processes described herein.

### DETAILED DESCRIPTION

This disclosure relates generally to the field of semiconductor processing. In particular aspects, the disclosure is directed to process and apparatus for cleaning of photoresists (e.g., EUV-sensitive metal and/or metal oxide-containing photoresists), for example to remove unintended photoresist deposited on a backside and bevel edge of a substrate in the context of photoresist patterning.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### Introduction

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography makes use of EUV resists that are patterned to form masks for use in etching underlying layers. EUV resists may be polymer-based chemically amplified resists (CARs) produced by liquid-based spin-on techniques. Alternatives to CARs are directly photopatternable metal oxide-containing films, such as those available from Inpria, Corvallis, OR, and described, for example, in US Patent Publications US 2017/0102612, US 2016/021660 and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Patent Application No. PCT/US2019/31618, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers.

During application of a photoresist film (e.g., EUV photoresist film) to a substrate, either by conventional wet, e.g., spin-on, processing or dry deposition, there may be some unintended deposition of resist material on the wafer backside and/or bevel edge. This backside and bevel edge deposition can cause downstream processing problems, including contamination of the patterning (scanner) and development tools. A high concentration of metallics from unintended metal-containing EUV resist material on backside and/or bevel edge regions of the wafer can cause an increased risk of metallics being released during downstream processing (e.g., EUV scanning, development). Such contamination can be detrimental to the performance of patterning and development tools as well as to film deposited on the frontside of the wafer. Conventionally, removal of this backside and bevel edge deposition is done by wet cleaning techniques.

The current state-of-the-art for cleaning spin-coated metal-organic photoresists is by wet-clean processing. An edge bead removal (EBR) is performed on a wet track on both the front and the backside of a wafer. A nozzle is positioned over the edge of the wafer on both the frontside and the backside of the wafer, and solvent is dispensed while the wafer is rotating. An organic solvent (for example: PGME, PGMEA, 2-heptanone) dissolves the photoresist on the edge, cleaning the bevel edge region. If the backside is contaminated, the wafer needs to go to another wet clean station for backside cleaning of the wafer. For spin-coating, the wafer region contacting the chuck typically remains clean and a separate backside clean is not always used. Additional cleans such as dilute hydrofluoric acid (dHF), dilute hydrochloric acid (dHCl), dilute sulfuric acid, or standard clean 1 (SC-1) may be necessary to reduce metals contamination. Before entering the EUV scanner, a backside scrub is commonly performed.

Solvents used in wet-clean processing inherently have issues of high cost for both acquisition and disposal. Such solvents may become hazardous to the environment and present health concerns. Wet-clean processing may be limited by uniformity of removal of the EUV resist material on the bevel edge regions. Due to surface tension and vapor concerns, the removal is often wavy and does not result in crisp removal of the EUV resist material at the bevel edge regions. Additionally, backsplashes using organic solvents can generate defects on the frontside of the wafer. The wet-clean processing is typically performed in a stand-alone tool/chamber, and so wafers need to be transferred after deposition in between tools/chambers. This can result in contamination of the tools/chambers used in backside and/or bevel edge cleaning.

### Backside and Bevel Edge Cleaning

The present disclosure provides for dry backside and bevel edge cleaning of unwanted material from a substrate. The dry backside and bevel edge clean is limited to specific regions to ensure removal of the material from backside and bevel edge regions without film degradation on the frontside of the substrate. In some embodiments, the unwanted material includes EUV resist material deposited on the backside and bevel edge regions of the substrate. In some embodiments, the unwanted material includes silicon-based films or carbon-based films. Dry backside and bevel edge clean is performed using an etch gas. The etch gas may be hydrogen gas, a hydrogen halide, hydrogen gas and a halide gas, or boron trichloride. A process chamber may be equipped with a substrate support having a plurality of minimum contact area (MCA) supports that elevate a substrate so that the etch gas can access the backside of the substrate. The substrate support may be a carrier ring. The etch gas may be delivered in a first etch gas flow from below the substrate support. A gas distributor may deliver curtain gas at a center of the frontside of the substrate to limit the etch gas from reaching the center of the frontside. The gas distributor may also deliver etch gas in a second etch gas flow at a periphery of the frontside of the substrate. A heat source such as a radiative heat source may be applied on the substrate during the dry backside and bevel edge clean. The radiative heat source may be positioned below the substrate support. Backside clean and bevel edge clean are both performed in the same process chamber. In some embodiments, deposition operations and the dry backside and bevel edge clean are performed in the same process chamber. In some embodiments, post-application bake (PAB) and dry backside and bevel edge clean are performed in the same process chamber. Integration of tools/chambers in a single chamber increases throughput, reduces costs, and reduces the likelihood of contamination that would otherwise occur in between transfers.

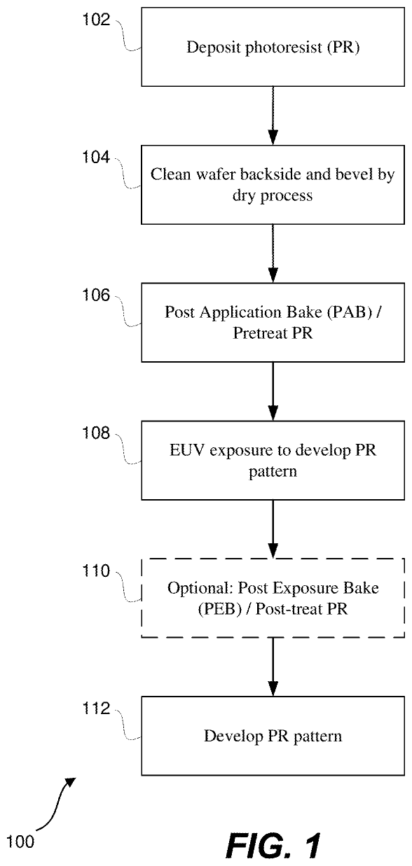

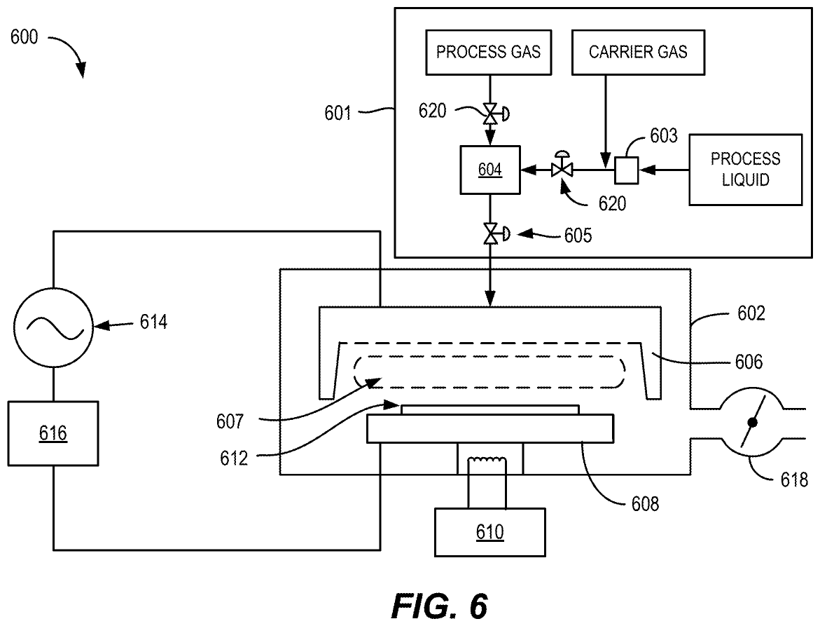

FIG. 1 presents a flow diagram of an example method for depositing and developing a photoresist according to some embodiments. The operations of a process 100 may be performed in different orders and/or with different, fewer, or additional operations. One or more operations of the process 100 may be performed using an apparatus described in any one of FIGS. 6-9. In some embodiments, the operations of the process 100 may be implemented, at least in part, according to software stored in one or more non-transitory computer readable media.

At block 102 of the process 100, a layer of photoresist is deposited. This may be either a dry deposition process such as a vapor deposition process or a wet process such as a spin-on deposition process.

The photoresist may be a metal-containing EUV resist. An EUV-sensitive metal or metal oxide-containing film may be deposited on a semiconductor substrate by any suitable technique, including wet (e.g., spin-on) or dry (e.g., CVD) deposition techniques. For example, described processes have been demonstrated for EUV photoresist compositions based on organotin oxides, being applicable to both commercially spin-coatable formulations (e.g., such as are available from Inpria Corp, Corvallis, OR) and formulations applied using dry vacuum deposition techniques, further described below. Though the photoresist described in the present disclosure is often described as a metal-containing EUV resist material, it will be understood that the process operations of the present disclosure may apply to any other films such as silicon-based films or carbon-based films.

Semiconductor substrates may include any material construct suitable for photolithographic processing, particularly for the production of integrated circuits and other semiconducting devices. In some embodiments, semiconductor substrates are silicon wafers. Semiconductor substrates may be silicon wafers upon which features have been created (“underlying features”), having an irregular surface topography. As referred to herein, the “surface” is a surface onto which a film of the present disclosure is to be deposited or that is to be exposed to EUV during processing. Underlying features may include regions in which material has been removed (e.g., by etching) or regions in which materials have been added (e.g., by deposition) during processing prior to conducting a method of this disclosure. Such prior processing may include methods of this disclosure or other processing methods in an iterative process by which two or more layers of features are formed on the substrate.

EUV-sensitive thin films may be deposited on the semiconductor substrate, such films being operable as resists for subsequent EUV lithography and processing. Such EUV-sensitive thin films comprise materials which, upon exposure to EUV, undergo changes, such as the loss of bulky pendant substituents bonded to metal atoms in low density M-OH rich materials, allowing their crosslinking to denser M-O-M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a more hydrophobic surface than the exposed film under the conditions at which such subsequent processing is performed. For example, the removal of material may be performed by leveraging differences in chemical composition, density and cross-linking of the film. Removal may be by wet processing or dry processing, as further described below.

The thin films are, in various embodiments, organometallic materials, for example organotin materials comprising tin oxide, or other metal oxide materials/moieties. The organometallic compounds may be made in a vapor phase reaction of an organometallic precursor with a counter reactant. In various embodiments, the organometallic compounds are formed through mixing specific combinations of organometallic precursors having bulky alkyl groups or fluoroalkyl groups with counter-reactants and polymerizing the mixture in the vapor phase to produce a low-density, EUV-sensitive material that deposits onto the semiconductor substrate.

In various embodiments, organometallic precursors comprise at least one alkyl group on each metal atom that can survive the vapor-phase reaction, while other ligands or ions coordinated to the metal atom can be replaced by the counter-reactants. Organometallic precursors include those of the formula:

MₐR_{b}L_{c} (Formula 1)

wherein: M is an element with a high patterning radiation-absorption cross-section; R is alkyl, such as CₙH₂ₙ₊₁, preferably wherein n=1-6; L is a ligand, ion or other moiety which is reactive with the counter-reactant; a≥1; b≥1; and c≥1.

In various embodiments, M has an atomic absorption cross section equal to or greater than 1×10⁷ cm²/mol. M may be, for example, selected from the group consisting of tin, hafnium, tellurium, bismuth, indium, iodine, antimony, germanium, and combinations thereof. In some embodiments, M is tin. R may be fluorinated, e.g., having the formula CₙFₓH₍₂ₙ₊₁₎. In various embodiments, R has at least one beta-hydrogen or beta-fluorine. For example, R may be selected from the group consisting of methyl, ethyl, i-propyl, n-propyl, t-butyl, i-butyl, n-butyl, sec butyl, n-pentyl, i-pentyl, t-pentyl, sec-pentyl, and mixtures thereof. L may be any moiety readily displaced by a counter-reactant to generate an M—OH moiety, such as a moiety selected from the group consisting of amines (such as dialkylamino, monoalkylamino), alkoxy, carboxylates, halogens, and mixtures thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(dimethylamino) tin, ethyl tris(dimethylamino) tin, and analogous alkyl(tris)(t-butoxy) tin compounds such as t-butyl tris(t-butoxy) tin. In some embodiments, the organometallic precursors are partially fluorinated.

Counter-reactants have the ability to replace the reactive moieties, ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di- or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or enhancing etch resistance. Such optional materials may be introduced, such as by doping during vapor phase formation prior to deposition on the semiconductor substrate, after deposition of the thin film, or both. In some embodiments, a gentle remote H₂ plasma may be introduced so as to replace some Sn—L bonds with Sn—H, which can increase reactivity of the resist under EUV.

In various embodiments, the EUV-patternable films are made and deposited on the semiconductor substrate using vapor deposition equipment and processes among those known in the art. In such processes, the polymerized organometallic material is formed in vapor phase or in situ on the surface of the semiconductor substrate. Suitable processes include, for example, chemical vapor deposition (CVD), atomic layer deposition (ALD), and ALD with a CVD component, such as a discontinuous, ALD-like process in which metal precursors and counter-reactants are separated in either time or space.

In general, methods comprise mixing a vapor stream of an organometallic precursor with a vapor stream of a counter-reactant so as to form a polymerized organometallic material, and depositing the organometallic material onto the surface of the semiconductor substrate. In some embodiments, more than one organometallic precursor is included in the vapor stream. In some embodiments, more than one counter-reactant is included in the vapor stream. As will be understood by one of ordinary skill in the art, the mixing and depositing aspects of the process may be concurrent, in a substantially continuous process.

In an example continuous CVD process, two or more gas streams, in separate inlet paths, of organometallic precursor and source of counter-reactant are introduced to the deposition chamber of a CVD apparatus, where they mix and react in the gas phase, to form agglomerated polymeric materials (e.g., via metal-oxygen-metal bond formation). The streams may be introduced, for example, using separate injection inlets or a dual-plenum showerhead. The apparatus is configured so that the streams of organometallic precursor and counter-reactant are mixed in the chamber, allowing the organometallic precursor and counter-reactant to react to form a polymerized organometallic material. Without limiting the mechanism, function, or utility of present technology, it is believed that the product from such vapor-phase reaction becomes heavier in molecular weight as metal atoms are crosslinked by counter-reactants, and is then condensed or otherwise deposited onto the semiconductor substrate. In various embodiments, the steric hindrance of the bulky alkyl groups prevents the formation of densely packed network and produces smooth, amorphous low-density films.

The CVD process is generally conducted at reduced pressures, such as from 10 mTorr to 10 Torr. In some embodiments, the process is conducted at from 0.5 to 2 Torr. In some embodiments, the temperature of the semiconductor substrate is at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature.

In some embodiments, the EUV-patternable films are made and deposited on the semiconductor substrate using wet deposition equipment and processes among those known in the art. For example, the organometallic material is formed by spin-coating on the surface of the semiconductor substrate.

The thickness of the EUV-patternable film formed on the surface of the semiconductor substrate may vary according to the surface characteristics, materials used, and processing conditions. In various embodiments, the film thickness may range from 0.5 nm to 100 nm, and may be a sufficient thickness to absorb most of the EUV light under the conditions of EUV patterning. The EUV-patternable film may be able to accommodate absorption equal to or greater than 30%, thereby having significantly fewer EUV photons available towards the bottom of the EUV-patternable film. Higher EUV absorption leads to more cross-linking and densification near the top of an EUV-exposed film compared to the bottom of the EUV-exposed film. Though insufficient cross-linking may cause the resist to be more prone to liftoff or collapse in wet development, such as risk is not as present in dry development. An all-dry lithography approach may facilitate more efficient utilization of EUV photons by more opaque resist films. Though efficient utilization of EUV photons may occur with EUV-patternable films having higher overall absorption, it will be understood that in some instances, the EUV-patternable film may be less than about 30%. For comparison, the maximum overall absorption of most other resist films is less than 30% (e.g., 10% or less, or 5% or less) so that the resist material at the bottom of the resist film is sufficiently exposed. In some embodiments, the film thickness is from 10 nm to 40 nm or from 10 nm to 20 nm. Without limiting the mechanism, function, or utility of present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

At block 104, a cleaning process is performed to clean a backside and bevel edge of the semiconductor substrate. The backside and bevel edge clean may non-selectively etch EUV resist film to equally remove film with various levels of oxidation or crosslinking on the substrate backside and bevel edge. During application of the EUV-patternable film, either by wet deposition processing or dry deposition processing, there may be some unintended deposition of resist material on the substrate bevel edge and/or backside. The unintended deposition may lead to undesirable particles later moving to a top surface of the semiconductor substrate and becoming particle defects. Moreover, this bevel edge and backside deposition can cause downstream processing problems, including contamination of the patterning (scanner) and development tools and metrology tools. Conventionally, removal of this bevel edge and backside deposition is done by wet cleaning techniques. However, the present disclosure provides removal of this bevel edge and backside deposition by dry cleaning techniques.

The backside and bevel edge clean may be a dry clean process. In some embodiments, the dry clean process involves a vapor and/or plasma having one or more of the following gases: HBr, HCl, HI, BCl₃, SOCl₂, Cl₂, BBr₃, H₂, O₂, PCl₃, CH₄, methanol, ammonia, formic acid, NF₃, HF. In some embodiments, the dry clean process may use the same chemistries as a dry development process described herein. For example, the backside and bevel edge clean may use hydrogen halide development chemistry. Alternatively, the backside and bevel edge clean may use an organic acid such as trifluoroacetic acid or other organic vapor. For the backside and bevel edge clean process, the vapor and/or the plasma has to be limited to a specific region of the substrate to ensure that only the backside and the bevel edge deposits are removed, without any film degradation on a frontside of the substrate.

Process conditions may be optimized for backside and bevel edge clean. In some embodiments, higher temperature, higher pressure, and/or higher reactant flow may lead to increased etch rate. Suitable process conditions for a dry bevel edge and backside clean may be: reactant flow of 100-10000 sccm (e.g., 500 sccm HCl, HBr, HI or H₂ and Cl₂, Br_{2,} or I₂, BCl₃, or H₂, or other halogen-containing compound), temperature of 20° C. to 140° C. (e.g., 80° C.), pressure of 20 mTorr to 1000 mTorr (e.g., 100 mTorr) or pressure of 50 Torr to 765 Torr (e.g., 760 Torr), plasma power of 0 W to 500 W at high frequency (e.g., 13.56 MHz), and for a time of about 10 to 20 seconds, dependent on the photoresist film and composition and properties. Bevel and/or backside clean may be accomplished using a Coronus® tool available from Lam Research Corporation, Fremont, CA, though a wider range of process conditions may be used according to the capabilities of the processing reactor.

Though the backside and bevel edge clean in block 104 is depicted prior to PAB treatment in block 106, it will be understood that the backside and bevel edge clean may be performed at any stage during the process 100 after deposition of the photoresist. Hence, the backside and bevel edge clean may be performed after photoresist deposition, after PAB treatment, after EUV exposure, after PEB treatment, or after development.

Bevel and/or backside clean may alternatively be extended to a full photoresist removal or photoresist “rework” in which an applied EUV photoresist is removed and the semiconductor substrate prepared for photoresist reapplication, such as when the original photoresist is damaged or otherwise defective. Photoresist rework should be accomplished without damaging the underlying semiconductor substrate, so an oxygen-based etch should be avoided. Instead, variants of halide-containing chemistries or organic vapor chemistries as described herein may be used. It will be understood that the photoresist rework operation may be applied at any stage during the process 100. Thus, the photoresist rework operation may be applied after resist deposition, after bevel edge and/or backside clean, after PAB treatment, after EUV exposure, after PEB treatment, after development, or after hard bake. In some embodiments, the photoresist rework may be performed for non-selective removal of exposed and unexposed regions of the photoresist but selective to an underlayer.

In some embodiments, the photoresist rework process involves a vapor and/or plasma having one or more of the following gases: HBr, HCl, HI, BCl₃, Cl₂, BBr₃, H₂, PCl₃, CH₄, methanol, ammonia, formic acid, NF₃, HF. In some embodiments, the photoresist rework may use the same chemistries as a dry development process described herein. For example, the photoresist rework may use hydrogen halide development chemistry or an organic acid such as trifluoroacetic acid or other organic vapor.

Process conditions may be optimized for the photoresist rework. In some embodiments, higher temperature, higher pressure, and/or higher reactant flow may lead to increased etch rate. Suitable process conditions for a photoresist rework may be: reactant flow of 100-500 sccm (e.g., 500 sccm HCl, HBr, HI, BCl₃ or H₂ and Cl₂ or Br₂), temperature of 20° C. to 140° C. (e.g., 80° C.), pressure of 20-1000 mTorr (e.g., 300 mTorr) or pressure of 50-765 Torr (e.g., 760 Torr), plasma power of 0 W to 800 W (e.g., 500 W) at high frequency (e.g., 13.56 MHz), wafer bias of 0 to 200 V_{b} (a higher bias may be used with harder underlying substrate materials) and for a time of about 20 seconds to 3 minutes, sufficient to completely remove the EUV photoresist, dependent on the photoresist film and composition and properties. In some embodiments, photoresist rework can be performed without application of plasma. The photoresist rework can be performed thermally with a halide-containing gas such as a hydrogen halide (e.g., HBr) at elevated temperatures (e.g., between 80° C.-120° C.). It should be understood that while these conditions are suitable for some processing reactors, e.g., a Kiyo etch tool available from Lam Research Corporation, Fremont, CA, a wider range of process conditions may be used according to the capabilities of the processing reactor.

At block 106 of the process 100, an optional post-application bake (PAB) is performed after deposition of the EUV-patternable film and prior to EUV exposure and/or after performing backside and bevel edge clean. The PAB treatment may involve a combination of thermal treatment, chemical exposure, and moisture to increase the EUV sensitivity of the EUV-patternable film, reducing the EUV dose to develop a pattern in the EUV-patternable film. The PAB treatment temperature may be tuned and optimized for increasing the sensitivity of the EUV-patternable film. For example, the treatment temperature may be between about 90° C. and about 200° C. or between about 150° C. and about 190° C. In some embodiments, the PAB treatment may be conducted with gas ambient flowing in the range of 100-10000 sccm, moisture content in the amount of a few percent up to 100% (e.g., 20%-50%), a pressure between atmospheric and vacuum, and a treatment duration of about 1 to 15 minutes, for example about 2 minutes. In some embodiments, the PAB treatment is conducted at a temperature between about 100° C. to 230° C. for about 1 minute to 2 minutes.

At block 108 of the process 100, the metal-containing EUV resist film is exposed to EUV radiation to develop a pattern. Generally speaking, the EUV exposure causes a change in the chemical composition and cross-linking in the metal-containing EUV resist film, creating a contrast in etch selectivity that can be exploited for subsequent development.

The metal-containing EUV resist film may then be patterned by exposing a region of the film to EUV light, typically under relatively high vacuum. EUV devices and imaging methods among those useful herein include methods known in the art. In particular, as discussed above, exposed areas of the film are created through EUV patterning that have altered physical or chemical properties relative to unexposed areas. For example, in exposed areas, metal-carbon bond cleavage may occur, as through a beta-hydride elimination, leaving behind reactive and accessible metal hydride functionality that can be converted to hydroxide and cross-linked metal oxide moieties via metal-oxygen bridges during a subsequent post-exposure bake (PEB) step. This process can be used to create chemical contrast for development as a negative tone resist. In general, a greater number of beta-H in the alkyl group results in a more sensitive film. This can also be explained as weaker Sn-C bonding with more branching. Following exposure, the metal-containing EUV resist film may be baked, so as to cause additional cross-linking of the metal oxide film. The difference in properties between exposed and unexposed areas may be exploited in subsequent processing, such as to dissolve unexposed areas or to deposit materials on the exposed areas. For example the pattern can be developed using a dry method to form a metal oxide-containing mask. Methods and apparatus among those useful in such processes are described in U.S. Patent Application 62/782,578, filed Dec. 20, 2018, incorporated by reference herein for its disclosure of the methods and apparatus.

In particular, in various embodiments, the hydrocarbyl-terminated tin oxide present on the surface is converted to hydrogen-terminated tin oxide in the exposed region(s) of an imaging layer, particularly when the exposure is performed in a vacuum using EUV. However, removing exposed imaging layers from vacuum into air, or the controlled introduction of oxygen, ozone, H₂O₂, or water, can result in the oxidation of surface Sn—H into Sn—OH. The difference in properties between exposed and unexposed regions may be exploited in subsequent processing, such as by reacting the irradiated region, the unirradiated region, or both, with one or more reagents to selectively add material to or remove material from the imaging layer.

Without limiting the mechanism, function or utility of present technology, EUV exposure, for example, at doses of from 10 mJ/cm² to 100 mJ/cm² results in the cleavage of Sn—C bonds resulting in the loss of the alkyl substituent, alleviating steric hindrance and allowing the low-density film to collapse. In addition, reactive metal-H bond generated in the beta-hydride elimination reactions can react with neighboring active groups such as hydroxyls in the film, leading to further cross-linking and densification, and creating chemical contrast between exposed and unexposed region(s).

Following exposure of the metal-containing EUV resist film to EUV light, a photopatterned metal-containing EUV resist is provided. The photopatterned metal-containing EUV resist includes EUV-exposed and unexposed regions.

At block 110 of the process 100, an optional post-exposure bake (PEB) is performed to further increase contrast in etch selectivity of the photopatterned metal-containing EUV resist. The photopatterned metal-containing EUV resist can be thermally treated in the presence of various chemical species to facilitate cross-linking of the EUV-exposed regions or simply baked on a hot plate in ambient air, for example between 100° C. and 250° C. for between one and five minutes (e.g., 190° C. for two minutes).

In various embodiments, a bake strategy involves careful control of the bake ambient, introduction of reactive gases, and/or careful control of the ramping rate of the bake temperature. Examples of useful reactive gases include e.g., air, H₂O, H₂O₂ vapor, CO₂, CO, O₂, O₃, CH₄, CH₃OH, N₂, H₂, NH₃, N₂O, NO, alcohol, acetyl acetone, formic acid, Ar, He, or their mixtures. The PEB treatment is designed to (1) drive complete evaporation of organic fragments that are generated during EUV exposure and (2) oxidize any Sn—H, Sn—Sn, or Sn radical species generated by EUV exposure into metal hydroxide, and (3) facilitate cross-linking between neighboring Sn—OH groups to form a more densely cross-linked SnO₂-like network. The bake temperature is carefully selected to achieve optimal EUV lithographic performance. Too low a PEB temperature would lead to insufficient cross-linking, and consequently less chemical contrast for development at a given dose. Too high a PEB temperature would also have detrimental impacts, including severe oxidation and film shrinkage in the unexposed region (the region that is removed by development of the patterned film to form the mask in this example), as well as, undesired interdiffusion at the interface between the photopatterned metal-containing EUV resist and an underlayer, both of which can contribute to loss of chemical contrast and an increase in defect density due to insoluble scum. The PEB treatment temperature may be between about 100° C. and about 300° C., between about 170° C. and about 290° C., or between about 200° C. and about 240° C. In some embodiments, the PEB treatment may be conducted with gas ambient flowing in the range of 100-10000 sccm, moisture content in the amount of a few percent up to 100% (e.g., 20%-50%), a pressure between atmospheric and vacuum, and a treatment duration of about 1 to 15 minutes, for example about 2 minutes. In some embodiments, PEB thermal treatment may be repeated to further increase etch selectivity.

At block 112 of the process 100, the photopatterned metal-containing EUV resist is developed to form a resist mask. In various embodiments, the exposed regions are removed (positive tone) or the unexposed regions are removed (negative tone). In some embodiments, development may include selective deposition on either the exposed or unexposed regions of the photopatterned metal-containing EUV resist, followed by an etching operation. In various embodiments, these processes may be dry processes or wet processes. Examples of processes for development involve an organotin oxide-containing EUV-sensitive photoresist thin film (e.g., 10-30 nm thick, such as 20 nm), subjected to a EUV exposure dose and post-exposure bake, and then developed. The photoresist film may be, for example, deposited based on a gas phase reaction of an organotin precursor such as isopropyl(tris)(dimethylamino)tin and water vapor, or may be a spin-on film comprising tin clusters in an organic matrix. The photopatterned metal-containing EUV resist is developed by exposure to a development chemistry. In some embodiments, the development chemistry includes a halide-containing chemistry or organic vapor such as trifluoroacetic acid.

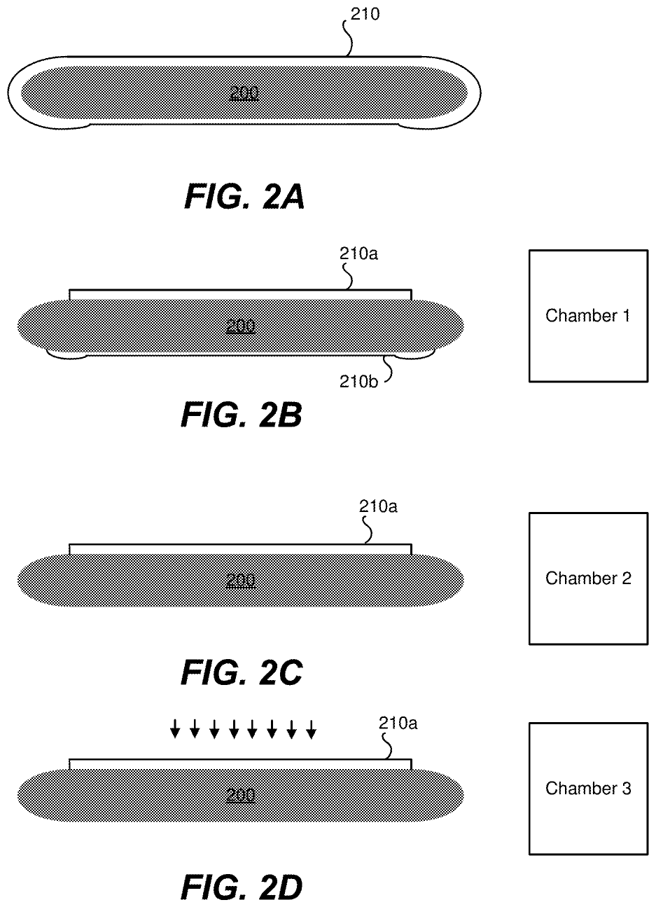

FIGS. 2A-2D show cross-sectional schematic illustrations of various processing stages of conventional backside and bevel edge clean. The conventional backside and bevel edge clean uses wet processing techniques. Deposition of EUV resist material may be performed using wet or dry deposition techniques.

As shown in FIG. 2A, the EUV resist material 210 may be deposited on the frontside, backside, and bevel edge of a substrate 200. The EUV resist material 210 deposited on the backside and bevel edge increases the likelihood of contamination on the frontside of the substrate 200 and contamination of downstream tools. Such EUV resist material 210 is unwanted. It is desired to remove EUV resist material 210 from the backside and bevel edge of the substrate 200. In some instances, it is desired to remove some EUV resist material 210 deposited on the frontside of the substrate 200, including EUV resist material 210 deposited at a periphery of the frontside of the substrate 200.

As shown in FIG. 2B, the EUV resist material 210 deposited on the bevel edge of the substrate 200 is removed by a wet bevel edge clean. This leaves EUV resist material 210a on the frontside of the substrate 200 and EUV resist material 210b on the backside of the substrate 200. In a standard edge bead removal process, organic solvent such as PGME, PGMEA, or 2-heptanone is dispensed to remove the EUV resist material 210 deposited on the bevel edge in a first process chamber (Chamber 1). The first process chamber may be a spin-clean tool. The organic solvent may be dispensed at a low/mild temperature such as about 20° C. Any heating of solvents which are flammable introduces a significant fire/explosion hazard. The substrate 200 undergoes rinse/dry operations before proceeding to a second process chamber (Chamber 2).

As shown in FIG. 2C, the EUV resist material 210b deposited on the backside of the substrate 200 is removed by a wet backside clean. This leaves the EUV resist material 210a on the frontside of the substrate 200. The wet backside clean may be performed in the second process chamber. The second process chamber may be another spin-clean tool that can clean the backside of the substrate 200. For example, the wet backside clean can employ cleaning agents such as dHF, dHCl, dilute sulfuric acid, or SC-1. The cleaning agent may be dispensed at a low/mild temperature such as about 20° C. The wet backside clean may also remove material on the bevel edge region, though it is typically ineffective in uniform or complete removal of material on the bevel edge region. Accordingly, backside cleans and bevel edge cleans are generally separated between the first process chamber and the second process chamber. The substrate 200 undergoes rinse/dry operations before proceeding to a third process chamber (Chamber 3).

As shown in FIG. 2D, the substrate 200 is transferred to the third process chamber to undergo PAB thermal treatment. In some embodiments, the third process chamber is an oven or includes a hot plate by which the substrate 200 is exposed to an elevated temperature. The PAB thermal treatment increases the substrate temperature to an elevated temperature such as between about 90° C. and 200° C. This stabilizes the lithography properties of the EUV resist material 210a on the frontside of the substrate 200 for EUV exposure. The PAB thermal treatment is a dry treatment.

In contrast to wet backside and bevel edge cleaning techniques, dry backside and bevel edge cleaning techniques may be less costly and more environmentally safe. Dry backside and bevel edge cleaning techniques may integrate chambers so that dry processing steps may be performed in fewer tools/chambers. Dry backside and bevel edge cleaning techniques may address non-uniformity issues related to wet backside and bevel edge cleaning techniques.

Existing dry backside and bevel edge cleaning techniques usually employ plasma to remove material from the backside and bevel edge of a substrate. Existing hardware may confine plasma to the backside and bevel edge of the substrate to remove material. However, plasma generates light, which can cause exposure of the frontside of the substrate to stray light and damage a photosensitive film. Furthermore, existing hardware is not effective in limiting residual etch gases from reaching the frontside of the substrate.

The present disclosure provides for dry backside and bevel edge cleaning without striking a plasma. Dry backside and bevel edge clean utilizes etch gas confined to specific regions of the substrate to remove material (e.g., EUV resist material) from the backside and bevel edge of the substrate. The dry backside and bevel edge clean exposes the substrate to an elevated temperature to promote non-selective removal of the material at the backside and bevel edge.

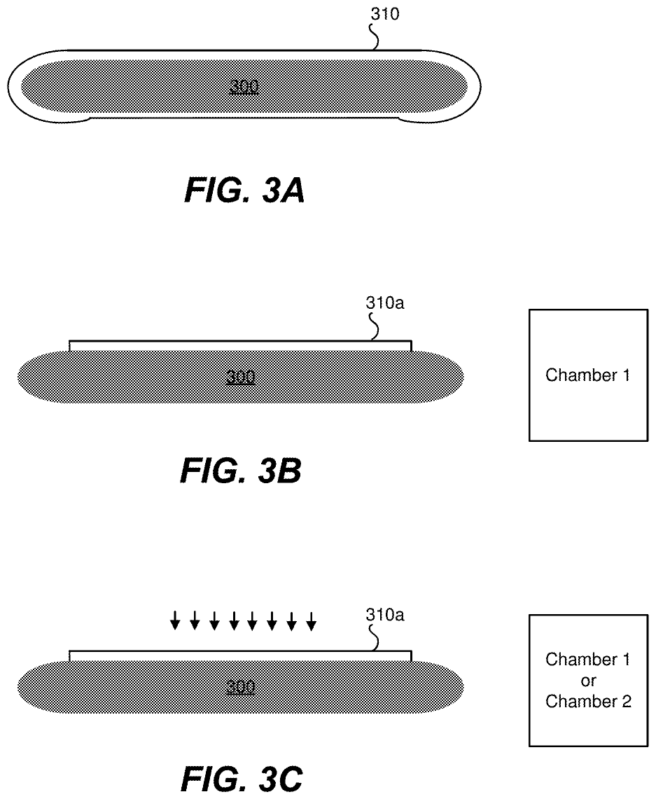

FIGS. 3A-3C show cross-sectional schematic illustrations of various processing stages of dry backside and bevel edge clean of photoresist material according to some embodiments. Deposition of photoresist material (e.g., EUV resist material) may be performed using wet or dry deposition techniques. Wet deposition techniques include spin-coating. Dry deposition techniques include chemical vapor deposition (CVD) or atomic layer deposition (ALD).

As shown in FIG. 3A, the EUV resist material 310 may be deposited on the frontside, backside, and bevel edge of a substrate 300. The EUV resist material 310 deposited on the backside and bevel edge increases the likelihood of contamination on the frontside of the substrate 300 and contamination of downstream tools. Such EUV resist material 310 is unwanted. It is desired to remove EUV resist material 310 from the backside and bevel edge of the substrate 300. In some instances, it is desired to remove some EUV resist material 310 deposited on the frontside of the substrate 300, including EUV resist material 310 deposited at a periphery of the frontside of the substrate 300. For instance, it may be desired to remove EUV resist material 310 about a few millimeters from the edge (e.g., about 1.5 mm) at the frontside. In some embodiments, the EUV resist material 310 is an organo-metal-containing resist material or organo-metal oxide. The EUV resist material 310 may include an element selected from a group consisting of: tin, hafnium, tellurium, bismuth, indium, antimony, iodine, and germanium. The element may have a high patterning radiation-absorption cross-section. In some embodiments, the element may have a high EUV-absorption cross-section. In some embodiments, the EUV resist material 310 may generally be composed of Sn, O, and C. For instance, the EUV resist material 310 includes organotin oxide.

As shown in FIG. 3B, the EUV resist material 310 deposited on the backside and bevel edge of the substrate 300 is removed by a dry clean. This leaves EUV resist material 310a at the frontside of the substrate 300. The dry clean may expose the backside and bevel edge of the substrate 300 to etch gas. In some embodiments, the etch gas is a hydrogen halide, hydrogen gas, hydrogen gas and halide gas, or boron trichloride (BCl₃). In one example, the etch gas is a hydrogen halide such as HCl, HBr, or HI. In another example, the etch gas is hydrogen gas (H₂). In yet another example, the etch gas is a mixture of H₂ with Cl₂, Br₂, or I₂. In still yet another example, the etch gas is BCl₃. In still yet another example, the etch gas is an organic acid such as trifluoroacetic acid. While this disclosure is not limited to any particular theory or mechanism of operation, the approach is understood to leverage the chemical reactivity of EUV photoresist materials with the clean chemistry (e.g., HCl, HBr, HI, H₂ and Cl₂, Br₂, or I₂, BCl₃) to form volatile products using vapors. The EUV photoresist materials may be removed using vapors at various temperatures, though higher temperatures, pressures, and/or reactant flow can further accelerate or enhance reactivity. In some embodiments, the EUV resist material can be removed with etch rates of up to 1 nm/s. In some embodiments, the etch gas is activated by a remote plasma source. This may further accelerate or enhance reactivity. In some embodiments, the etch gas is delivered with a carrier gas such as argon, helium, nitrogen, or other suitable carrier gas.

In some embodiments, the photoresist material is not EUV resist material, but a silicon-based material or carbon-based material. The etch gas for removal of such materials may be different than for removal of EUV resist material. In some embodiments, the etch gas includes an oxidizing gas such as O₂, CO₂, N₂O, and the like for removal of carbon-based materials. In some embodiments, the etch gas includes a fluorine-based gas such as CₓF_{y} or CₓF_{y}H_{z} or chlorine-based gas for removal of silicon-based materials.

An inert curtain gas may be delivered on the frontside of the substrate 300 to limit the etch gas to the backside and bevel edge of the substrate 300. The curtain gas may include gases such as nitrogen (N₂), oxygen (O₂), water (H₂O), argon (Ar), helium (He), xenon (Xe), neon (Ne), or mixtures thereof. The curtain gas is flowed on the frontside of the substrate 300 to protect at least central regions of the frontside of the substrate 300 from the etch gas. As the curtain gas is flowed to the frontside, the curtain gas spreads across the frontside to protect EUV resist material 310a deposited on the frontside.

The curtain gas may be flowed simultaneously with the etch gas. A first etch gas flow may be introduced to the backside of the substrate 300. The first etch gas flow may spread across the backside of the substrate 300, where the backside of the substrate 300 may be accessible when the substrate 300 is supported by MCA supports on a carrier ring. In some embodiments, a second etch gas flow may be introduced to the periphery of the frontside of the substrate 300. The second etch gas flow may flow along the periphery of the frontside and wrap around the bevel edge of the substrate 300. The first etch gas flow may be introduced from one or more bottom gas inlets positioned below the substrate support, and the second etch gas flow may be introduced from one or more peripheral gas inlets of a gas distributor positioned above the substrate support. The gas distributor may include a modular ring with the one or more peripheral gas inlets. The modular ring may modulate spacing between the one or more peripheral gas inlets and the frontside of the substrate 300. In some embodiments, curtain gas is flowed from one or more central gas inlets of the gas distributor, where a first gap separating the one or more peripheral gas inlets from the frontside is greater than a second gap separating the one or more central gas inlets from the frontside.

The substrate 300 may be heated to an elevated temperature during the dry clean, where the elevated temperature is between about 20° C. and about 170° C., between about 20° C. and about 140° C., between about 40° C. and about 140° C., or about 100° C. In some embodiments, the dry clean may be performed at an elevated pressure. The pressure in a process chamber may be between about 0.02 Torr and atmospheric pressure, between 0.1 Torr and atmospheric pressure, or between about 1 Torr and atmospheric pressure. In some embodiments, the dry clean may be performed with a high flow rate of the etch gas. The etch gas flow rate may be between about 50 sccm and about 10000 sccm, between about 100 sccm and about 10000 sccm, or between about 200 sccm and about 5000 sccm. Unlike wet cleaning techniques, the non-plasma thermal cleaning technique of the present disclosure can tune process parameters such as temperature, pressure, and gas flow rate to control etch rate. A high etch rate may be achieved to remove unexposed EUV resist material with higher temperature and/or pressure and flow rate.

Both backside clean and bevel edge clean are performed in a first process chamber (Chamber 1) rather than in separate process chambers. This reduces the likelihood of contamination of tools that may otherwise occur in between cleaning operations. A single pass may be performed for essentially multiple process steps in a single tool. This also reduces cost and increases throughput. No wet cleaning or rinse/dry operations are performed in the dry backside and bevel edge clean of the present disclosure.

In some embodiments, the dry backside and bevel edge clean includes exposure to etch gas followed by purging. Purging introduces a purge gas to pump/purge residual etch gas from the first process chamber. It will be understood that purging may be useful to remove residual etch gases or etch byproducts from the process chamber to avoid undesired etching of the frontside of the substrate 300 during substrate transfer. Purging may flow an inert gas and/or a reactive gas. The reactive gas may react with the residual etch gas to facilitate ease of removal. The reactive gas may be, for example, a tin-based precursor such as an organotin precursor. The inert gas may be Ar, He, Ne, Xe, or N₂. The chamber pressure may be between about 0.1 Torr and about 6 Torr. The purge gas flow may be between about 10 sccm and about 10000 sccm or between about 50 sccm and about 5000 sccm. In some embodiments, the pump/purge may proceed at a high temperature such as between about 20° C. and about 140° C. or between about 80° C. and about 120° C. The high temperature may facilitate removal of residual etch gas from the first process chamber. In some embodiments, chamber walls and other components may be heated to release residual etch gas. The residual etch gas (e.g., halide gas or halide-containing gas) may be exhausted through an exhaust line during pumping/purging. In some embodiments, the pump/purge operation may also be referred to as dehalogenation. Halides may readily stick to chamber walls, chamber components, or wafers. If the halides stick to the wafer, there is an increased risk of the halides (e.g., bromine) being released from the wafer during EUV scanning, thereby corroding or damaging the scanner.

In some embodiments, the duration of the backside and bevel edge clean is between about 10 seconds and about 150 seconds. In some embodiments, the endpoint of the backside and bevel edge clean is detected by one or more sensors. The one or more sensors may detect the presence of absence of EUV resist deposits on the backside and bevel edge of the substrate 300. The one or more sensors may include an IR sensor and/or optical sensor.

As shown in FIG. 3C, the substrate 300 is exposed to a PAB thermal treatment. In some embodiments, the PAB thermal treatment is performed in the same process chamber as the dry backside and bevel edge clean (i.e., first process chamber). That way, the dry backside and bevel edge clean is integrated with the PAB thermal treatment. This may further reduce the likelihood of contamination, reduce cost, and increase throughput. This may have minimal impact or positive impact on lithography performance. In some embodiments, the PAB thermal treatment is performed in a second process chamber (Chamber 2) that is different than the dry backside and bevel edge clean. The PAB treatment is a dry treatment.

The PAB thermal treatment increases the substrate temperature to an elevated temperature such as between about 100° C. and about 170° C. or between about 120° C. and about 150° C. In some embodiments, the substrate temperature may be controlled using a radiative heat source such as an IR lamp or one or more LEDs. The radiative heat source may be positioned below the substrate 300. Alternatively, the radiative heat source may be positioned above the substrate 300. The substrate temperature may be actively controlled by a pyrometer in a feedback control loop established with the radiative heat source. The atmosphere during PAB thermal treatment may be controlled by flowing inert gases such as N₂, Ar, He, Xe, or Ne, where the inert gases may be mixed with O₂ and/or H₂O. The flow rate of the inert gases may be between about 10 sccm and about 10000 sccm or between about 50 sccm and about 5000 sccm. The pressure during PAB thermal treatment may be controlled to be between about 0.02 Torr and atmospheric pressure, between about 0.1 Torr and atmospheric pressure, or between about 1 Torr and atmospheric pressure.

### Apparatus

The present disclosure provides hardware components in a process chamber for enabling dry backside and bevel edge clean while protecting central portions of the frontside of the substrate. The hardware components may be implemented in dry backside and bevel edge clean as well as in PAB treatment.

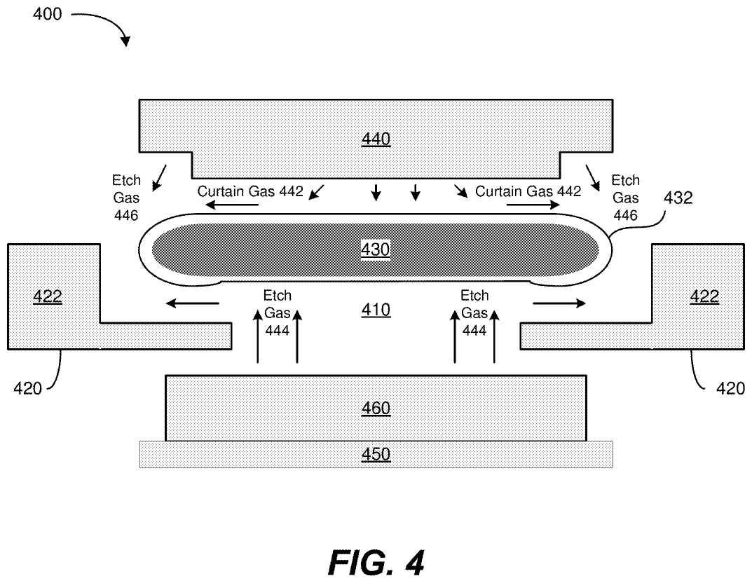

FIG. 4 shows a schematic illustration of a process chamber for performing dry backside and bevel edge clean according to some embodiments. An apparatus or tool 400 for performing dry backside and bevel edge clean may include a process chamber 410. The process chamber 410 may be integrated to not only perform both backside clean and bevel edge clean, but also PAB treatment and/or deposition. The apparatus 400 may include a substrate support 420 in the process chamber 410 for supporting a substrate 430. In some embodiments, the substrate support 420 may receive the substrate 430 after deposition of material (e.g., EUV resist material 432) on the frontside, backside, and bevel edge of the substrate 430. A plurality of minimum contact area supports (not shown) may be configured to extend from a major surface of the substrate support 420 to elevate the substrate 430 so that etch gas can access a backside of the substrate 430. The apparatus 400 further includes a gas distributor 440 over the substrate support 420 and coupled to the process chamber 410 for delivering curtain gas 442 to a frontside of the substrate 430. The apparatus 400 further includes an etch gas delivery source 450 below the substrate support 420 and coupled to the process chamber 410 for delivering etch gas 444 to a backside of the substrate 430. The apparatus 400 may further include a heat source 460 such as a radiative heat source below the substrate support 420.

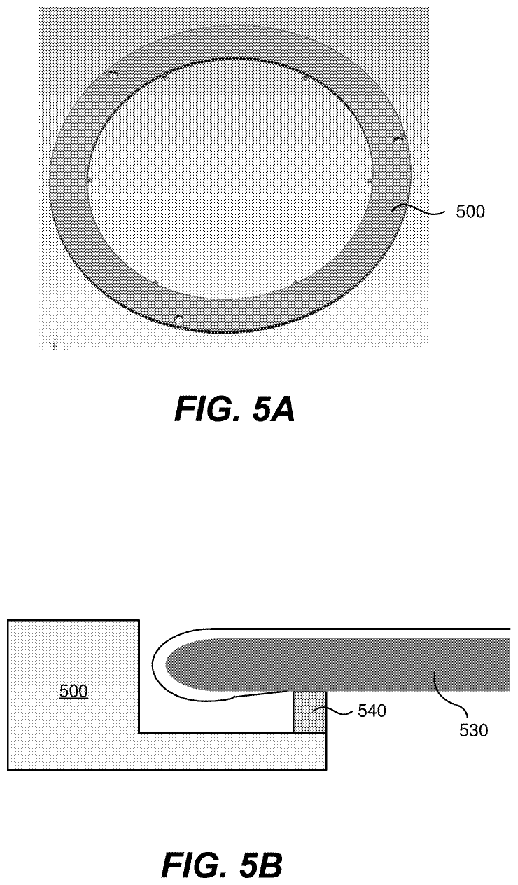

The substrate support 420 may include a carrier ring 422. The carrier ring 422 may have an annular body for supporting the substrate 430. FIG. 5A shows a perspective view of a carrier ring 500 for supporting a substrate 530 in a process chamber according to some embodiments. A substrate 530 in the semiconductor industry typically has a diameter of 200 mm, 300 mm, or 450 mm. An outer diameter of the carrier ring 500 is greater than the diameter of the substrate 530 and an inner diameter of the annular body is less than the diameter of the substrate 530. The inner diameter may equal to or less than about 280 mm, equal to or less than about 240 mm, or equal to or less than about 200 mm. In other words, the substrate 530 may be gripped by a ring with a radius equal to or less than about 140 mm. A plurality of MCA supports 540 may extend from a major surface of the carrier ring 500 to contact the backside of the substrate 530. In some embodiments, the plurality of MCA supports 540 may be symmetrically arranged about a center of the carrier ring 500. For instance, the plurality of MCA supports 540 may include three MCA supports, four MCA supports, five MCA supports, six MCA supports, or more. The MCA supports 540 may be pins. The plurality of MCA supports 540 may include any suitable insulating material. The insulating material may be a soft material such as a perfluoroalkoxy alkane (PFA) to avoid scratching the substrate 530. FIG. 5B shows a cross-sectional schematic illustration of a carrier ring 500 supporting and contacting a backside of a substrate 530 according to some embodiments.

The position of the MCA supports 540 may be optimized to the preceding deposition process to avoid contacting the substrate 530 where it has backside deposition. Put another way, the plurality of MCA supports 540 may be configured to contact areas of the backside of the substrate 530 where there is little to no backside deposition (e.g., photoresist deposits). This placement may be determined based on knowledge or data ascertained from one or more previous deposition operations indicating where there is little to no backside deposition. For example, the MCA supports 540 may contact the backside of the substrate 530 in areas closer to a center of the substrate 530 than an edge of the substrate 530. At the same time, the position of the MCA supports 540 does not prevent the etch gas from accessing areas with backside deposition.

The plurality of MCA supports 540 provide minimal contact with the backside of the substrate 530. The plurality of MCA supports 540 may elevate the substrate 530 above a major surface of the carrier ring 500 to a height to permit gas flow across the backside of the substrate 530. In some embodiments, the height is between about 0.025 mm and about 0.5 mm or between about 0.05 mm and about 0.25 mm. In some embodiments, the MCA supports 540 are extendable/retractable from the major surface of the substrate support. In some embodiments the height is adjustable so that gap size is controlled. In some embodiments, the backside of the substrate 530 is supported by MCA supports 540 with a shifting mechanism or rotation mechanism in order to be able to clean the area directly touched by the MCA supports 540 and the substrate 530. The etch gas may be blocked by accessing the area in direct contact with the MCA support 540. Even though the area is very small in relation to the substrate 530 it may still have an unacceptable high metal contamination. Therefore, this area needs to be cleaned as well. In other words, the MCA supports 540 may shift or rotate positions to contact different points of the backside of the substrate 530. The shifting mechanism may be incorporated into lift pins which are used during substrate transfer. After the first part of the clean which cleans the whole substrate 530 except the area touched by the MCA supports 540, the carrier ring 500 may lower the substrate 530 onto the lift pins. The lift pins move the substrate by a multiple of the MCA area, e.g., about tens of microns. Afterwards the carrier ring 500 moves back into process position and a second clean is performed to clean the areas first touched by the MCA supports 540. In some embodiments, the backside of the substrate 530 is supported by a section of MCA supports 540, where the carrier ring 500 is divided into two or more sections of X number of MCA supports 540 each, where X is any integer value. In this case the clean process may be split into several time steps. During each time step one or more of the parts of the split ring is moved away from the substrate surface enabling the clean in that section. All sections have to at least been lifted/cleaned once during the clean. A minimum number of section(s) needs to stay in place for the substrate 530 to be held securely in the process position. For example, the carrier ring 500 may be split into two sections of three pins each. The carrier ring 500 and the plurality of MCA supports 540 may be configured in a manner to modulate etch gas flow in the backside of the substrate 530. Specifically, the height of the MCA supports 540, the inner diameter of the carrier ring 500, the positioning of the MCA supports 540, and other aspects of the carrier ring 500 may be designed to modulate gas flow between the curtain gas from the top and the etch gas from the bottom to ensure that both the backside and the bevel edge are etched but not certain regions of the frontside of the substrate 530.

Returning to FIG. 4, an etch gas delivery source 450 and a radiative heat source 460 may be positioned below the substrate support 420 (e.g., carrier ring). The etch gas delivery source 450 may include one or more bottom gas inlets or nozzles for delivering etch gas 444 to the backside of the substrate 430. The radiative heat source 460 may be spaced apart from the backside of the substrate 430 but may heat the substrate 430 to an elevated temperature by radiative heating. The radiative heat source 460 may provide controlled ramp capability, pulsing, and rapid changes in temperature. In some embodiments, the radiative heat source 460 includes one or more IR lamps or one or more LEDs. To enable rapid changes of temperature the heat source may be in the 1-10 kW range. In some embodiments, the substrate support 420 may be configured to rotate. For controllability of the substrate temperature, the one or more IR lamps or the one or more LEDs may be separated into zones for controlled heating of various regions of the substrate 430. Additionally, the one or more lamps or the one or more LEDs may each be independently controllable. By pulsing the LEDs, a temperature ramp up of the substrate 430 can be controlled. The radiative heat source 460 may also serve to block stray light from reaching the frontside of the substrate 430. In some embodiments, the etch gas delivery source 450 includes one or more holes through the radiative heat source 460. In some embodiments, the etch gas delivery source 450 includes one or more holes positioned outside of the radiative heat source 460. The positioning of the one or more holes may not be critical as uniformity of etch gas flow on the backside of the substrate 430 is not critical for removal of material on the backside of the substrate 430. Thus, the etch gas delivery source 450 may be positioned in any manner so that the etch gas 444 is able to reach or otherwise access the backside of the substrate 430.

A gas distributor 440 is positioned above the substrate support 420 for delivering curtain gas 442 to the frontside of the substrate 430. The gas distributor 440 may include one or more central gas inlets for directing curtain gas flow at a center of the frontside of the substrate 430. In some embodiments, the gas distributor 440 may include one or more peripheral gas inlets for directing an etch gas flow 446 at a periphery of the frontside of the substrate 430. It will be understood that the periphery of the frontside of the substrate 430 may occupy an area of 15% or less, 10% or less, or 5% or less of the frontside of the substrate 430. In some embodiments, the gas distributor 440 includes a top plate with multiple holes arranged in a central region of the top plate and multiple holes arranged in a peripheral region of the top plate. In some embodiments, the gas distributor 440 includes modular rings of different diameters. In some instances, the modular rings may have different shapes. Etch gas 446 may be delivered through one of the modular rings, and curtain gas 442 may be delivered through another one of the modular rings. Thus, the gas distributor 440 includes at least a modular ring for the one or more peripheral gas inlets, where the at least one modular ring is configured to modulate spacing of the one or more peripheral gas inlets from the frontside of the substrate 430. Removal at the bevel edge can be modulated by modulating the spacing of the one or more peripheral gas inlets in the modular ring. Additionally or alternatively, the gas distributor 440 includes one or more nozzles for directing etch gas flow 446 at the bevel edge of the substrate 430.

The gas distributor 440 may be configured so that a first gap separating the one or more peripheral gas inlets front the frontside of the substrate 430 is greater than a second gap separating the one or more central gas inlets from the frontside of the substrate 430. In some embodiments, the first gap is at least two times greater than the second gap. The second gap may be as small as possible without touching the EUV resist film 432 on the frontside of the substrate 430. As shown in FIG. 4, the gas distributor 440 may have a stepped design. That way, curtain gas flow 442 may be provided at a higher pressure and delivered across a smaller gap at a center of the substrate 430 and etch gas flow 446 may be provided at a lower pressure and delivered across a larger gap at a periphery of the substrate 430. The etch gas flow 446 delivered from above the substrate support 420 may be referred to as the “second etch gas flow,” whereas the etch gas flow 444 delivered from below the substrate support 420 may be referred to as the “first etch gas flow.” The second etch gas flow delivered at the periphery of the substrate 430 may wrap around parts of the frontside and the bevel edge region of the substrate 430. For instance, the second etch gas flow may wrap around 5 mm or less, around 3 mm or less, or 1.5 mm or less of the frontside of the substrate 430. The curtain gas flow 442 prevents etch gas from reaching a remainder of the frontside of the substrate 430.

In addition or in the alternative to the radiative heat source 460, the apparatus 400 may further include one or more heaters. The one or more heaters may provide substrate temperature control. In some embodiments, the one or more heaters are coupled to the gas distributor 440 and above the substrate 430. The one or more heaters may be radiative heat sources. In some embodiments, the one or more heaters are configured to provide ambient heating in the process chamber 410. In some embodiments, the one or more heaters provide substrate temperature control in the range of 20° C. to 170° C. or 20° C. to 140° C.

The apparatus 400 may further include one or more sensors for detecting a presence of film deposits on the backside and/or bevel edge of the substrate 430. In some embodiments, the one or more sensors include an optical device such as an IR sensor that serves as an endpoint detection.

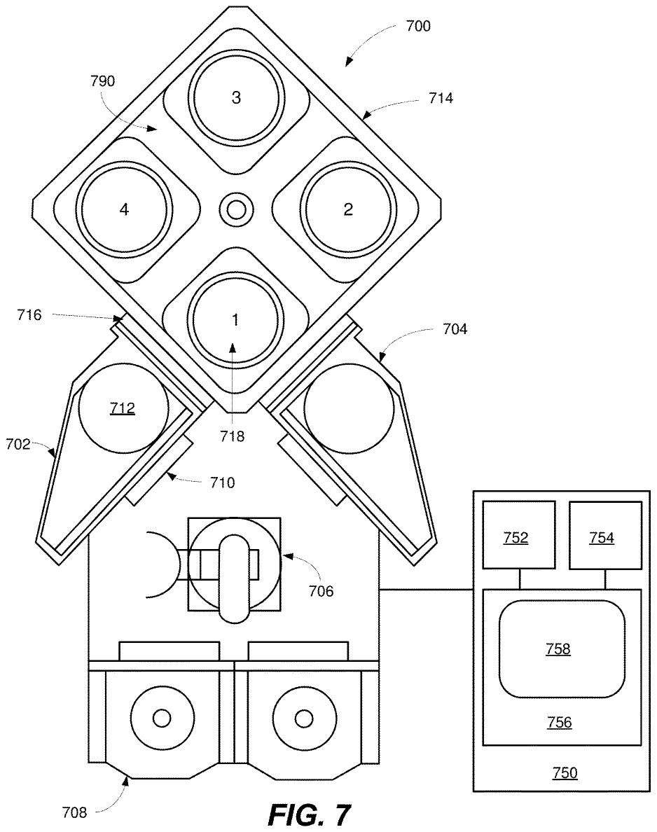

FIG. 6 depicts a schematic illustration of an embodiment of process station 600 having a process chamber body 602 for maintaining a low-pressure environment that is suitable for embodiment of described dry backside and bevel edge clean embodiments. A plurality of process stations 600 may be included in a common low pressure process tool environment. For example, FIG. 7 depicts an embodiment of a multi—station processing tool 700, such as a VECTOR® processing tool available from Lam Research Corporation, Fremont, CA. In some embodiments, one or more hardware parameters of the process station 600 including those discussed in detail below may be adjusted programmatically by one or more computer controllers 650.

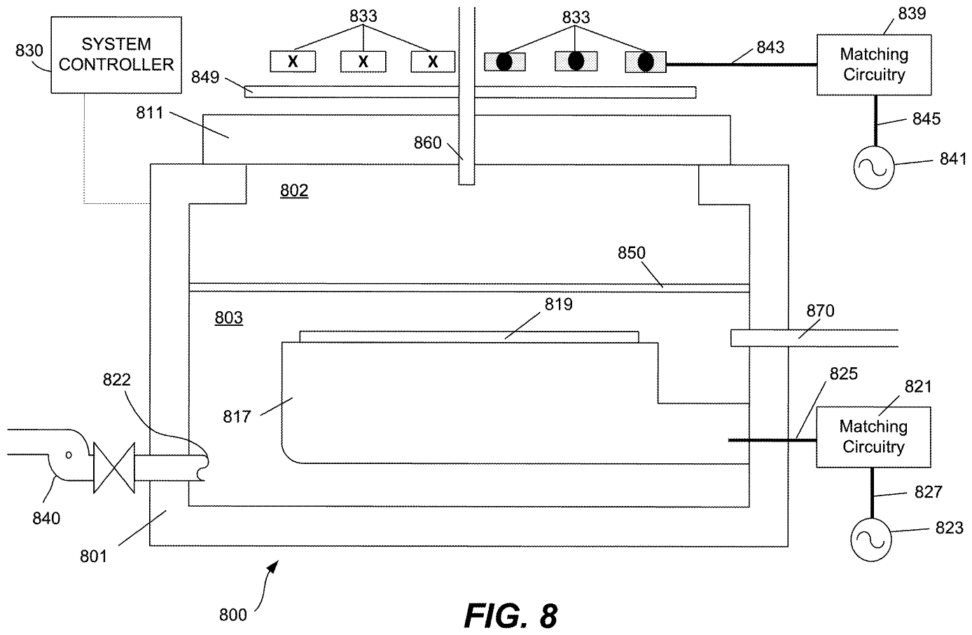

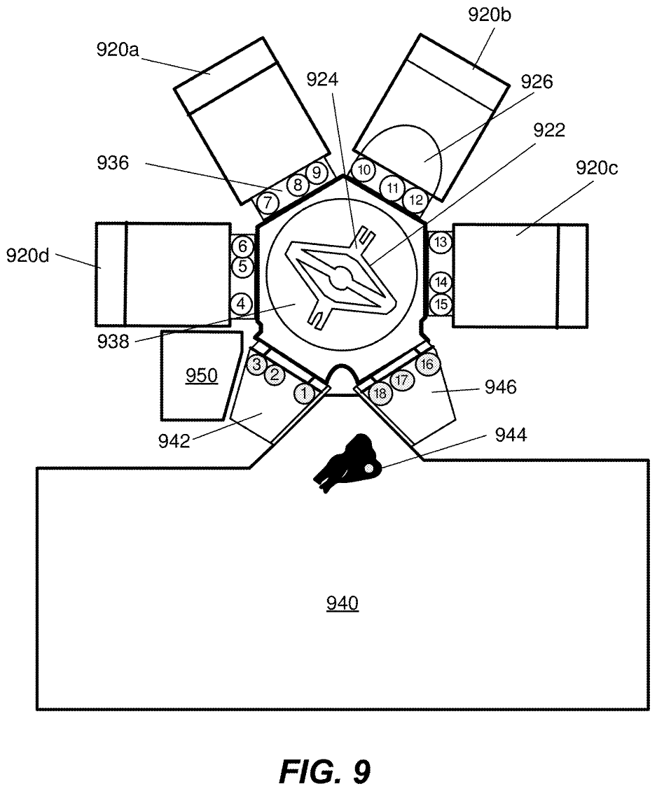

A process station may be configured as a module in a cluster tool. FIG. 9 depicts a semiconductor process cluster tool architecture with vacuum-integrated deposition and patterning modules suitable for implementation of the embodiments described herein. Such a cluster process tool architecture can include resist deposition, resist exposure (EUV scanner), resist development and etch modules, as described above and further below with reference to FIGS. 8 and 9.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 6, process station 600 fluidly communicates with reactant delivery system 601a for delivering process gases to a distribution showerhead 606. Reactant delivery system 601a optionally includes a mixing vessel 604 for blending and/or conditioning process gases, for delivery to showerhead 606. One or more mixing vessel inlet valves 620 may control introduction of process gases to mixing vessel 604. Where plasma exposure is used, plasma may also be delivered to the showerhead 606 or may be generated in the process station 600. As noted above, in at least some embodiments, non-plasma thermal exposure is favored.

FIG. 6 includes an optional vaporization point 603 for vaporizing liquid reactant to be supplied to the mixing vessel 604. In some embodiments, a liquid flow controller (LFC) upstream of vaporization point 603 may be provided for controlling a mass flow of liquid for vaporization and delivery to process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 606 distributes process gases toward substrate 612. In the embodiment shown in FIG. 6, the substrate 612 is located beneath showerhead 606 and is shown resting on a pedestal 608. Showerhead 606 may have any suitable shape, and may have any suitable number and arrangement of ports for distributing process gases to substrate 612.

In some embodiments, pedestal 608 may be raised or lowered to expose substrate 612 to a volume between the substrate 612 and the showerhead 606. It will be appreciated that, in some embodiments, pedestal height may be adjusted programmatically by a suitable computer controller 650. In some embodiments, the showerhead 606 may have multiple plenum volumes with multiple temperature controls. In some embodiments, the pedestal 608 may be replaced by a carrier ring for supporting the substrate 612.

In some embodiments, pedestal 608 may be temperature controlled via heater 610. Alternatively, the substrate 612 supported by a carrier ring may be heated by a radiative heat source positioned below the substrate 612. In some embodiments, the substrate 612 may be heated to a temperature of greater than 0° C. and up to 300° C. or more, for example 50 to 120° C., such as about 65 to 80° C., during non-plasma thermal exposure of a resist to dry backside and bevel edge clean chemistry, such as HBr or HCl, as described in disclosed embodiments. In some embodiments, the heater 610 of the pedestal 608 may include a plurality of independently controllable temperature control zones.

Further, in some embodiments, pressure control for process station 600 may be provided by a butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

Where plasma may be used, for example in gentle plasma-based dry clean embodiments and/or etch operations conducted in the same chamber, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are up to about 500 W.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry clean chemistry reactant gas, such as HBr or HCl, and time delay instructions for the recipe phase. In some embodiments, the controller 650 may include any of the features described below with respect to system controller 750 of FIG. 7.

As described above, one or more process stations may be included in a multi-station processing tool. FIG. 7 shows a schematic view of an embodiment of a multi-station processing tool 700 with an inbound load lock 702 and an outbound load lock 704, either or both of which may include a remote plasma source. A robot 706 at atmospheric pressure is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 includes a remote plasma source, the wafer may be exposed to a remote plasma treatment to treat the silicon nitride surface in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 7 includes load locks, it will be appreciated that, in some embodiments, direct entry of a wafer into a process station may be provided.

The depicted processing chamber 714 includes four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. For example, in some embodiments, a process station may be switchable between dry clean and deposition process modes. Additionally or alternatively, in some embodiments, processing chamber 714 may include one or more matched pairs of dry clean and deposition process stations. While the depicted processing chamber 714 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 7 depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog, and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. Alternatively, the control logic may be hard coded in the controller 750. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 758 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 700. System control software 758 may be configured in any suitable way. For example, various process tool component subroutines or control objects may be written to control operation of the process tool components used to carry out various process tool processes. System control software 758 may be coded in any suitable computer readable programming language.

In some embodiments, system control software 758 may include input/output control (IOC) sequencing instructions for controlling the various parameters described above. Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling halide-containing gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 750 may provide program instructions for implementing the above-described deposition processes. The program instructions may control a variety of process parameters, such as DC power level, RF bias power level, pressure, temperature, etc. The instructions may control the parameters to operate development and/or etch processes according to various embodiments described herein.

The system controller 750 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some embodiments, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 1450 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some embodiments, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a development chamber or module, and any other semiconductor processing systems that may be associated or used in the fabrication and/or manufacturing of semiconductor wafers.

As noted above, depending on the process step or steps to be performed by the tool, the system controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 8 schematically shows a cross-sectional view of an inductively coupled plasma apparatus 800 appropriate for implementing certain embodiments or aspects of embodiments such as dry backside and bevel edge clean, an example of which is a Kiyo® reactor, produced by Lam Research Corp. of Fremont, CA. In other embodiments, other tools or tool types having the functionality to conduct the dry backside and bevel edge clean described herein may be used for implementation.

The inductively coupled plasma apparatus 800 includes an overall process chamber 824 structurally defined by chamber walls 801 and a window 811. The chamber walls 801 may be fabricated from stainless steel, aluminum, or plastic. The window 811 may be fabricated from quartz or other dielectric material. An optional internal plasma grid 850 divides the overall process chamber into an upper sub-chamber 802 and a lower sub chamber 803. In most embodiments, plasma grid 850 may be removed, thereby utilizing a chamber space made of sub chambers 802 and 803. A chuck 817 is positioned within the lower sub-chamber 803 near the bottom inner surface. The chuck 817 is configured to receive and hold a semiconductor wafer 819 upon which the etching and deposition processes are performed. The chuck 817 can be an electrostatic chuck for supporting the wafer 819 when present. In some embodiments, an edge ring (not shown) surrounds chuck 817, and has an upper surface that is approximately planar with a top surface of the wafer 819, when present over chuck 817. The chuck 817 also includes electrostatic electrodes for chucking and dechucking the wafer 819. A filter and DC clamp power supply (not shown) may be provided for this purpose. Other control systems for lifting the wafer 819 off the chuck 817 can also be provided. The chuck 817 can be electrically charged using an RF power supply 823. The RF power supply 823 is connected to matching circuitry 821 through a connection 827. The matching circuitry 821 is connected to the chuck 817 through a connection 825. In this manner, the RF power supply 823 is connected to the chuck 817. In various embodiments, a bias power of the electrostatic chuck may be set at about 50 V or may be set at a different bias power depending on the process performed in accordance with disclosed embodiments. For example, the bias power may be between about 20 Vb and about 100 V, or between about 30 V and about 150 V.

Elements for plasma generation include a coil 833 is positioned above window 811. In some embodiments, a coil is not used in disclosed embodiments. The coil 833 is fabricated from an electrically conductive material and includes at least one complete turn. The example of a coil 833 shown in FIG. 8 includes three turns. The cross sections of coil 833 are shown with symbols, and coils having an “X” extend rotationally into the page, while coils having a “●” extend rotationally out of the page. Elements for plasma generation also include an RF power supply 541 configured to supply RF power to the coil 833. In general, the RF power supply 841 is connected to matching circuitry 839 through a connection 845. The matching circuitry 839 is connected to the coil 833 through a connection 843. In this manner, the RF power supply 841 is connected to the coil 833. An optional Faraday shield 849a is positioned between the coil 833 and the window 811. The Faraday shield 849a may be maintained in a spaced apart relationship relative to the coil 833. In some embodiments, the Faraday shield 849a is disposed immediately above the window 811. In some embodiments, the Faraday shield 849b is between the window 811 and the chuck 817. In some embodiments, the Faraday shield 849b is not maintained in a spaced apart relationship relative to the coil 833. For example, the Faraday shield 849b may be directly below the window 811 without a gap. The coil 833, the Faraday shield 849a, and the window 811 are each configured to be substantially parallel to one another. The Faraday shield 849a may prevent metal or other species from depositing on the window 811 of the process chamber 824.

Process gases may be flowed into the process chamber through one or more main gas flow inlets 860 positioned in the upper sub-chamber 802 and/or through one or more side gas flow inlets 870. Likewise, though not explicitly shown, similar gas flow inlets may be used to supply process gases to a capacitively coupled plasma processing chamber. A vacuum pump, e.g., a one or two stage mechanical dry pump and/or turbomolecular pump 840, may be used to draw process gases out of the process chamber 824 and to maintain a pressure within the process chamber 824. For example, the vacuum pump may be used to evacuate the lower sub-chamber 803 during a purge operation of ALD. A valve-controlled conduit may be used to fluidically connect the vacuum pump to the process chamber 824 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 800, one or more process gases may be supplied through the gas flow inlets 860 and/or 870. In certain embodiments, process gas may be supplied only through the main gas flow inlet 860, or only through the side gas flow inlet 870. In some cases, the gas flow inlets shown in the figure may be replaced by more complex gas flow inlets, one or more showerheads, for example. The Faraday shield 849a and/or optional grid 850 may include internal channels and holes that allow delivery of process gases to the process chamber 824. Either or both of Faraday shield 849a and optional grid 850 may serve as a showerhead for delivery of process gases. In some embodiments, a liquid vaporization and delivery system may be situated upstream of the process chamber 824, such that once a liquid reactant or precursor is vaporized, the vaporized reactant or precursor is introduced into the process chamber 824 via a gas flow inlet 860 and/or 870.

Radio frequency power is supplied from the RF power supply 841 to the coil 833 to cause an RF current to flow through the coil 833. The RF current flowing through the coil 533 generates an electromagnetic field about the coil 833. The electromagnetic field generates an inductive current within the upper sub-chamber 802. The physical and chemical interactions of various generated ions and radicals with the wafer 819 etch features of and selectively deposit layers on the wafer 819.

If the plasma grid 850 is used such that there is both an upper sub-chamber 802 and a lower sub-chamber 803, the inductive current acts on the gas present in the upper sub-chamber 802 to generate an electron-ion plasma in the upper sub-chamber 802. The optional internal plasma grid 850 limits the amount of hot electrons in the lower sub-chamber 803. In some embodiments, the apparatus 800 is designed and operated such that the plasma present in the lower sub-chamber 803 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 803 through port 822. The chuck 817 disclosed herein may operate at elevated temperatures ranging between about 10° C. and about 250° C. The temperature will depend on the process operation and specific recipe.

Apparatus 800 may be coupled to facilities (not shown) when installed in a clean room or a fabrication facility. Facilities include plumbing that provide processing gases, vacuum, temperature control, and environmental particle control. These facilities are coupled to apparatus 800, when installed in the target fabrication facility. Additionally, apparatus 800 may be coupled to a transfer chamber that allows robotics to transfer semiconductor wafers into and out of apparatus 800 using typical automation.

In some embodiments, a system controller 830 (which may include one or more physical or logical controllers) controls some or all of the operations of a process chamber 824. The system controller 830 may include one or more memory devices and one or more processors. In some embodiments, the apparatus 800 includes a switching system for controlling flow rates and durations when disclosed embodiments are performed. In some embodiments, the apparatus 800 may have a switching time of up to about 500 ms, or up to about 750 ms. Switching time may depend on the flow chemistry, recipe chosen, reactor architecture, and other factors.

In some embodiments, the system controller 830 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 830, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 830 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 830, in some embodiments, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 830 receives instructions in the form of data, which specify parameters for each of the processing steps to be performed during one or more operations. It should be understood that the parameters may be specific to the type of process to be performed and the type of tool that the controller is configured to interface with or control. Thus as described above, the system controller 830 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 9 depicts a semiconductor process cluster tool architecture with vacuum-integrated deposition, backside and bevel edge clean, EUV patterning and dry development/etch modules that interface with a vacuum transfer module, suitable for implementation of the processes described herein. While the processes may be conducted without such vacuum integrated apparatus, such apparatus may be advantageous in some embodiments.

FIG. 9 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 938 interfaces with four processing modules 920a-920d, which may be individually optimized to perform various fabrication processes. By way of example, processing modules 920a-920d may be implemented to perform deposition, evaporation, ELD, dry development, etch, strip, and/or other semiconductor processes. For example, module 920a may be an ALD reactor that may be operated to perform in a non-plasma, thermal atomic layer depositions as described herein, such as Vector tool, available from Lam Research Corporation, Fremont, CA. And module 920b may be a PECVD tool, such as the Lam Vector®. It should be understood that the figure is not necessarily drawn to scale.

Airlocks 942 and 946, also known as a loadlocks or transfer modules, interface with the VTM 938 and a patterning module 940. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 9 but without the integrated patterning module.

Airlock 942 may be an “outgoing” loadlock, referring to the transfer of a substrate out from the VTM 938 serving a deposition module 920a to the patterning module 940, and airlock 946 may be an “ingoing” loadlock, referring to the transfer of a substrate from the patterning module 940 back in to the VTM 938. The ingoing loadlock 946 may also provide an interface to the exterior of the tool for access and egress of substrates. Each process module has a facet that interfaces the module to VTM 938. For example, deposition process module 920a has facet 936. Inside each facet, sensors, for example, sensors 1-18 as shown, are used to detect the passing of wafer 926 when moved between respective stations. Patterning module 940 and airlocks 942 and 946 may be similarly equipped with additional facets and sensors, not shown.

Main VTM robot 922 transfers wafer 926 between modules, including airlocks 942 and 946. In one embodiment, robot 922 has one arm, and in another embodiment, robot 922 has two arms, where each arm has an end effector 924 to pick wafers such as wafer 926 for transport. Front-end robot 944, in is used to transfer wafers 926 from outgoing airlock 942 into the patterning module 940, from the patterning module 940 into ingoing airlock 946. Front-end robot 944 may also transport wafers 926 between the ingoing loadlock and the exterior of the tool for access and egress of substrates. Because ingoing airlock module 946 has the ability to match the environment between atmospheric and vacuum, the wafer 926 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 942 may provide this function by holding the transferred wafers at a lower pressure, no higher than the pressure in the patterning module 940, for a period of time and exhausting any off-gassing, so that the optics of the patterning tool 940 are not contaminated by off-gassing from the substrate. A suitable pressure for the outgoing, off-gassing airlock is no more than 1 E-8 Torr.

In some embodiments, a system controller 950 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 950 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, developing the photopatterned resist, and etching the underlying layer or layer stack using the patterned resist as a mask. Development may be performed using a halide-containing chemistry.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 6, 7 or 8 may be implemented with the tool in FIG. 9.

### Conclusion

Process and apparatus for dry development of metal and/or metal oxide photoresists, for example to form a patterning mask in the context of EUV patterning is disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

What is claimed is:

1. A method of conducting bevel edge and backside clean of a substrate, the method comprising:
providing a substrate on a substrate support in a process chamber, wherein the substrate comprises a photoresist material on a frontside, bevel edge, and backside of the substrate, wherein the substrate is lifted above the substrate support to permit gas flow across the backside of the substrate;
heating the substrate to an elevated temperature, wherein the elevated temperature is between about 20° C. and about 170° C.;
flowing curtain gas to a center of the frontside of the substrate;
flowing a first etch gas flow of an etch gas to the backside of the substrate to remove at least the photoresist material from the backside of the substrate; and
flowing a second etch gas flow of an etch gas to a periphery of the frontside of the substrate to remove at least the photoresist material from the bevel edge of the substrate.

2. The method of claim 1, wherein the first etch gas flow is flowed across the backside of the substrate, wherein the second etch gas flow is flowed along a periphery of the frontside the substrate and the bevel edge of the substrate, wherein the curtain gas limits the etch gas from flowing to a center of the frontside of the substrate.

3. The method of claim 1, wherein the substrate is heated to the elevated temperature using a radiative heat source below the substrate support.

4. The method of claim 1, further comprising:
lifting the substrate over the substrate support using a plurality of MCA supports to create a gap between the substrate support and the backside of the substrate.

5. The method of claim 1, further comprising:
dry depositing the photoresist material on the frontside, bevel edge, and backside of the substrate, wherein the deposition occurs in the same process chamber as removing at least the photoresist material from the bevel edge of the substrate and the backside of the substrate.

6. The method of claim 1, wherein the photoresist material comprises an EUV resist material.

7. The method of claim 1, wherein the photoresist material comprises an organo-metal-oxide material.

8. The method of claim 1, wherein the first etch gas flow is flowed from one or more bottom gas inlets below the substrate support and wherein the second etch gas flow is flowed from one or more peripheral gas inlets of a gas distributor above the substrate support.

9. The method of claim 8, wherein the curtain gas is flowed from one or more central gas inlets of the gas distributor above the substrate support.

10. The method of claim 9, wherein a first gap separating the one or more peripheral gas inlets from the frontside of the substrate is greater than a second gap separating the one or more central gas inlets from the frontside of the substrate.

11. The method of claim 1, wherein the etch gas comprises a hydrogen halide, hydrogen gas and halide gas, or boron trichloride.

12. The method of claim 11, wherein the etch gas comprises a hydrogen halide.

13. The method of claim 1, wherein the curtain gas comprises nitrogen (N₂), oxygen (O₂), water (H₂O), argon (Ar), helium (He), xenon (Xe), or neon (Ne).

14. The method of claim 1, further comprising:
performing a post-application bake on the photoresist material by heating the substrate to a desired temperature in the same process chamber for removing the photoresist material from the bevel edge and backside of the substrate.

15. The method of claim 1, further comprising:
purging the process chamber with purge gas after removing the photoresist material from the bevel edge and backside of the substrate.
